(19) United States
(12) Patent Application Publication
(10) Pub. No.: US 2001/0041406 A1
(43) Pub. Date: Nov. 15, 2001

(54) Method of producing electrodes of a micromechanical or microelectronic device

(76) Inventors: Bernd Goebel, Dresden (DE); Martin Gutsche, Dorfen (DE)

Correspondence Address: LERNER AND GREENBERG, P.A., POST OFFICE BOX 2480, HOLLYWOOD, FL, 33022-2480, US

(21) Appl. No.: 09/732,152

(22) Filed: Dec. 7, 2000

(30) Foreign Application Priority Data
Dec. 7, 1999 (DE) 199 58 907.0

(51) Int. Cl. H01L 21/8242; H01L 21/20

(52) U.S. Cl. 438/255; 438/398

(57) ABSTRACT

A method for producing electrodes in a micromechanical or microelectronic device, includes the steps of producing a shape-imparting supporting structure in or on a substrate; enlarging the surface of the shape-imparting supporting structure; and molding the electrodes, using the enlarged-surface, shape-imparting supporting structure.

### BACKGROUND OF THE INVENTION

### FIELD OF THE INVENTION

The present invention relates to a method for producing electrodes in a micromechanical or microelectronic device.

Although the invention can be used for any micromechanical or microelectronic device, the invention and the problem that the invention solves will be explained with reference to a stack capacitor in a semiconductor device.

Such stack capacitors, which are used in particular in DRAMs (dynamic random access memory), should have as great a capacitance as possible. The capacitance is directly proportional to the electrode area.

However, in addition to the electrode area of the capacitor and the dielectric used, the electrode materials also play a decisive part in the resultant capacitance. By choosing a suitable electrode material, it is possible to increase the achievable capacitance. If Ta₂O₅ is used, for example, approximately twice the capacitance may be achieved if a metal (e.g. tungsten nitride) is used instead of polysilicon. Furthermore, certain dielectrics having very high dielectric constants (e.g. BST=barium-strontium titanate) need electrodes made of materials which, to some extent, can be structured only with difficulty (e.g. metals such as Pt and Ir, and various conductive oxides such as IrO₂, or conductive ceramic materials such as SrRuO).

In order to produce the electrodes of stack capacitors, in the processes which are usual nowadays, polysilicon is predominantly used, since, using the processes which have hitherto been available, a sufficiently roughened capacitor area may be achieved only with this material. Polysilicon is distinguished by the fact that it can experience a considerable enlargement of its surface, for example as a result of HSG formation (HSG=hemispherical grain). For metallic electrode materials, hitherto no similar process for enlarging the surface is known.

### SUMMARY OF THE INVENTION

It is accordingly an object of the invention to provide a method for producing electrodes in a micromechanical or microelectronic device which permits the implementation of an enlarged electrode area in electrode materials which as such are difficult to structure with regard to the desired surface enlargement.

With the foregoing and other objects in view there is provided, in accordance with the invention, a method of producing electrodes in a micromechanical device or a microelectronic device, the method includes the steps of:

producing a shape-imparting supporting structure on or in a substrate;

enlarging a surface of the shape-imparting supporting structure for providing an enlarged-surface, shape-imparting supporting structure; and

molding electrodes by using the enlarged-surface, shape-imparting supporting structure.

The invention is based on the idea that a surface enlargement process, such as a roughening process can be combined with a molding or filling process in order to form a molded electrode structure. The supporting structures used are materials whose surface can be enlarged in a conventional way. The enlarged surface can thus also be transferred to electrode materials whose surface cannot be enlarged in a simple, straightforward way.

The process according to the invention has the particular advantage, as compared to the conventional solution, that the good properties of specific electrode materials can be used synergetically with the tried and tested technologies of surface enlargement.

According to a preferred mode of the invention, a positive molding process is carried out.

According to a further preferred mode of the invention, the positive molding is carried out through the use of the following steps: forming the enlarged-surface, shape-imparting supporting structure on the surface of the substrate; filling the enlarged-surface, shape-imparting supporting structure with a filler material; exposing the top of the filled, enlarged-surface, shape-imparting supporting structure; removing the enlarged-surface, shape-imparting supporting structure from the exposed top in order to form cavities; and filling the cavities with the electrode material in order to form the electrodes.

According to a further preferred mode of the invention, the cavities are filled with the electrode material in such a way that, first of all, the entire surface is covered and then the electrode material is removed as far as the top of the filler material, in other words down to the level of the filler material.

According to a further preferred mode of the invention, the cavities are filled with the electrode material in such a way that the electrode material is grown from the bottom as far as the top of the filler material.

According to another preferred mode of the invention, the filler material is removed during the positive molding process.

According to another preferred mode of the invention, a negative molding process is carried out.

According to another preferred mode of the invention, the negative molding is carried out through the use of the following steps: forming the enlarged-surface, shape-imparting supporting structure on the surface of the substrate; and filling the enlarged-surface, shape-imparting supporting structure with the electrode material.

According to a further preferred mode of the invention, the cavities are filled with the electrode material in such a way that, first of all, the entire surface is covered and then the electrode material is removed down to the level of the top of the enlarged-surface, shape-imparting supporting structure.

According to another preferred mode of the invention, the cavities are filled with the electrode material in such a way that the electrode material is grown from the bottom as far as the top of the enlarged-surface, shape-imparting supporting structure.

According to a further preferred mode of the invention, the filler material or enlarged-surface, shape-imparting structure is removed during the negative molding process.

According to a further preferred mode of the invention, in order to enlarge the surface, one of the following processes is used: a HSG formation in polysilicon; a nucleation island growth, in particular of polysilicon on an amorphous underlayer, such as SiN or SiO₂; forming standing waves in a photoresist; or providing mesospores in silicon.

According to a further preferred mode of the invention, one of the following processes is used for the filling step: a chemical vapor-phase deposition (CVD), an ALCVD (atomic layer CVD), an electrochemical deposition or a spin-on application.

According to a further preferred mode of the invention, first of all, for example by the CVD process, a first electrode material is deposited into the shape-imparting supporting structure as a thin layer. The remaining volume is then filled with a second electrode material. Multiple layers of a number of electrode materials can also be formed before the remaining volume is filled with the second electrode material.

According to a further preferred mode of the invention, the exposing step is carried out through the use of a CMP (chemical mechanical polishing) step or an etch-back step.

According to a further preferred mode of the invention, the electrode material is selected from the following group: Pt, Ir, IrO₂, Ru, RuO₂, SrₓRu_{y}O_{z}, W, WN, WSi, Ta, TaN, Ti, TiN, Mo, MoN, Al.

Other features which are considered as characteristic for the invention are set forth in the appended claims.

Although the invention is illustrated and described herein as embodied in a process for producing electrodes of a micromechanical or microelectronic device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1a-1h are diagrammatic, partial sectional views of a structure illustrating a first embodiment of the process according to the invention with a positive molding;

FIGS. 2a-2e are diagrammatic, partial sectional views of a structure illustrating a second embodiment of the process according to the invention with a negative molding; and

FIGS. 3a-3d are diagrammatic, partial sectional views of a structure illustrating a third embodiment of the process according to the invention with a positive molding and an electrochemical deposition.

### DESCRIPTION OF THE PREFERRED EMBODIMENTS

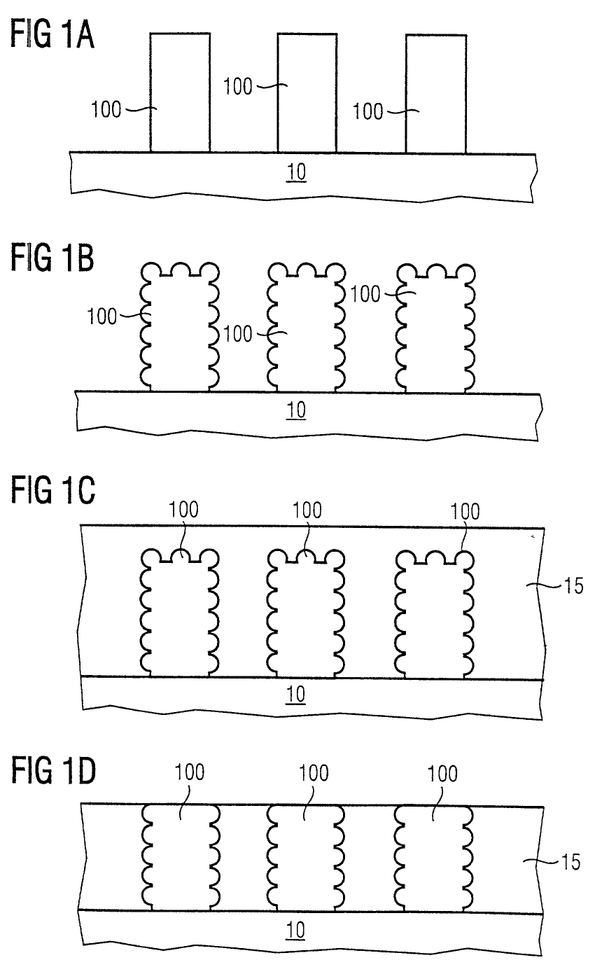

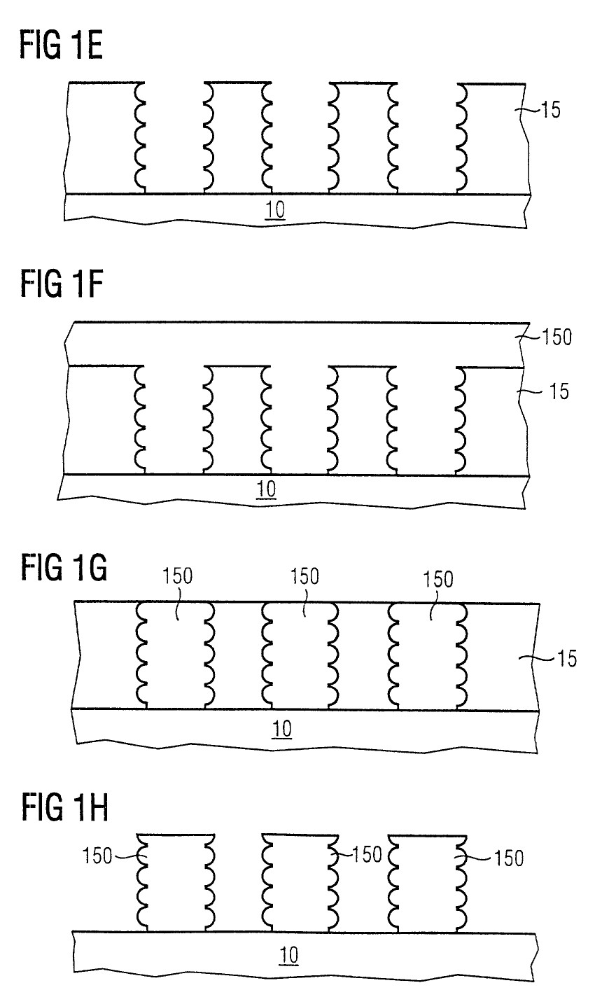

Referring now to the figures of the drawings in detail, in which identical reference symbols designate identical or functionally identical component parts, and first, particularly, to FIGS. 1a-1h thereof, there is illustrated a first embodiment of the process according to the invention using a positive molding process.

As FIG. 1a shows, first of all a polysilicon structure 100, which has rectangular trenches and elevations, is produced on a semiconductor substrate 10. The elevations predefine the subsequent electrode shape.

Then, as shown in FIG. 1b, the surface of the polysilicon of the elevations 100 is populated with a large number of silicon grains through the use of HSG formation, which leads to a considerable enlargement of the surface.

According to FIG. 1c, the trenches or interspaces are then filled with a filler material, expediently SiO₂ or SiN. Another option for filling would be a spin-on process, such as FOX (flowable oxide).

In the following step, as shown in FIG. 1d, the filler material 15 is removed over the whole area down to the top of the polysilicon elevations 100. A CMP process (CMP=Chemical Mechanical Polishing) or an etch-back through the use of ion-assisted processes, for example, are suitable for this purpose.

After that, as FIG. 1e shows, the polysilicon of the polysilicon elevations 100 is dissolved out of the supporting structure which is formed by the filler material 15. Wet chemical or plasma-chemical etching processes are suitable for this purpose.

As FIG. 1f shows, the desired electrode material 150 is then put into the shape produced in this way, for example by a CVD process (CVD=Chemical Vapor Deposition).

The next step is the removal of the electrode material over the entire area down to the shape-imparting material 15, in order to separate the electrodes 150. This can be brought about by a further CMP process or by an etch-back step. This results in the structure shown in FIG. 1g.

Finally, the filler material 15, which is still between the electrodes can be dissolved out through the use of an etching process (for example a wet-chemical process or a plasma-assisted process) in order to obtain the desired electrode array, as illustrated in FIG. 1h.

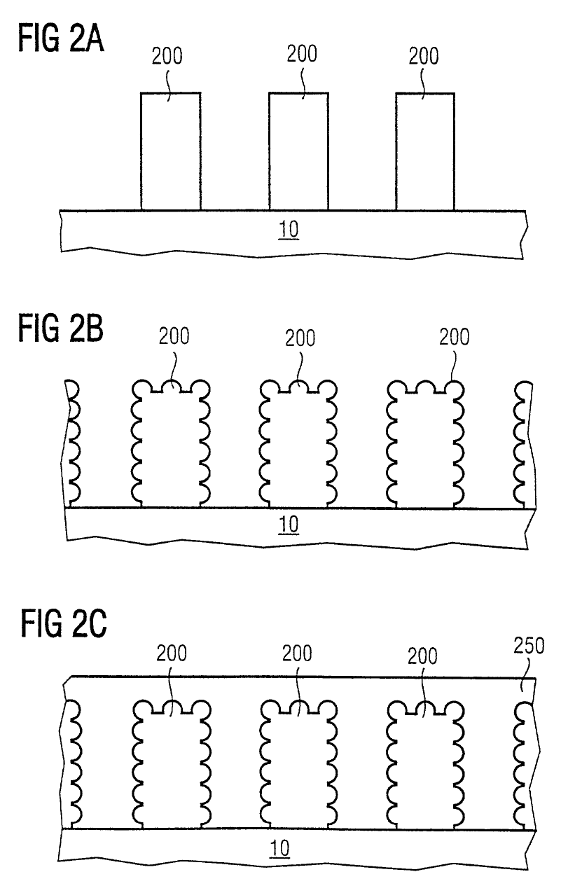

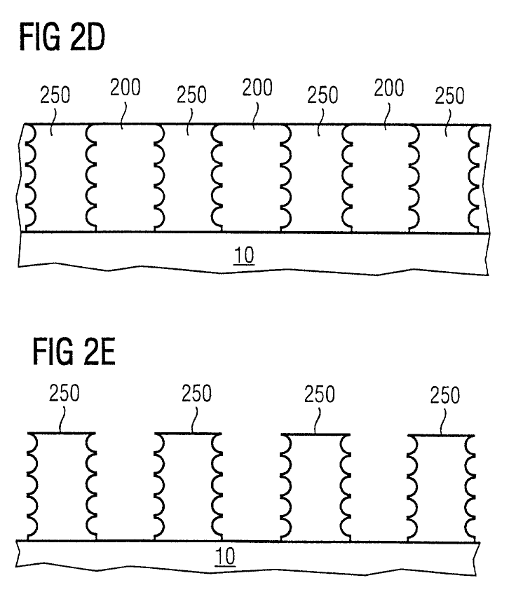

FIGS. 2a-e show a second embodiment of the process according to the invention using a negative molding process.

According to FIG. 2a, in this second exemplary embodiment, exactly as in the first exemplary embodiment, a polysilicon structure 200 with trenches and elevations is formed, for example by holes being etched through the use of an etching mask into a polysilicon layer deposited over the entire area.

After that, the surface of the elevations 200 is roughened through the use of an HSG process, in order to obtain a significantly enlarged surface, as shown in FIG. 2b.

According to FIG. 2c, the desired electrode material 250 is then put into the shape produced in this way, for example by a CVD process.

In the next step, the electrode material 250 is removed over the entire area down to the shape-imparting polysilicon 200, for example through the use of a CMP process or through the use of an etch-back step, in order to obtain the structure shown in FIG. 2d.

In the last step, in a manner similar to the first embodiment, the shape-imparting polysilicon between the electrodes 250 can then be dissolved out (with a wet-chemical or plasma-assisted process) in order to obtain the desired electrode array by negative molding, as shown in FIG. 2e.

In a slight modification of the embodiments previously described, other materials, including for example SiO₂, can be used instead of the polysilicon for the starting layer into which the holes are etched. The roughening of the surface can then be performed through the use of conventional or modified HSG formation on SiO₂. However, when the shape-imparting material is being dissolved out at the end, it is necessary to take care that two different materials have to be removed.

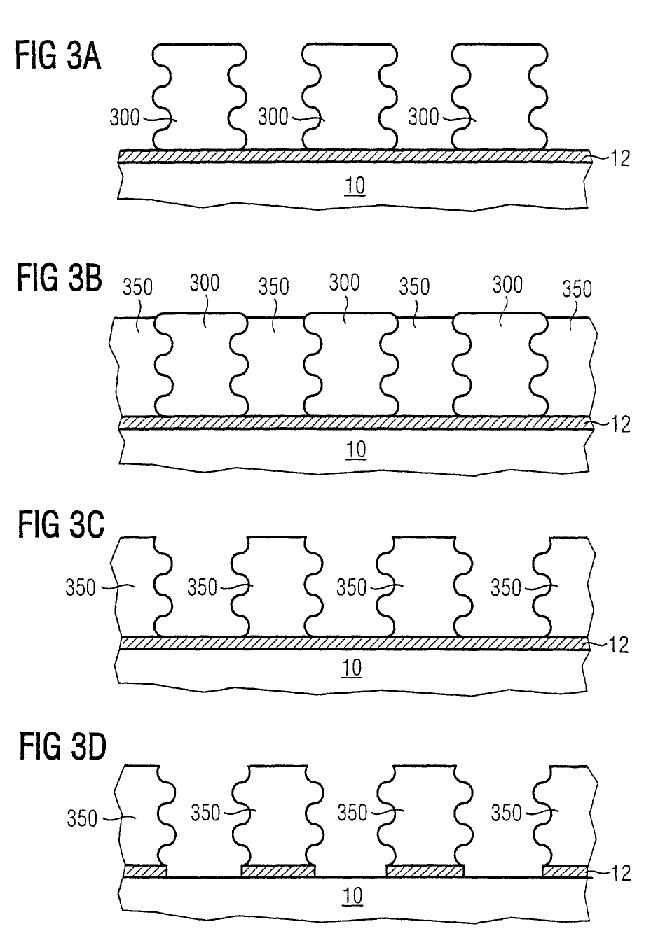

FIGS. 3a-d show a third embodiment of the process according to the invention wherein the mold or shape is filled through the use of an electrochemical deposition process.

In the embodiment shown in FIGS. 3a to 3d, the electrode material 350 between the supporting structures 300 is grown in the previously formed mold or shape through the use of an electrochemical deposition. This is suitable, in particular, for specific metals, such as platinum. In addition, however, a seed layer 12 underneath the shape-imparting layer and on the substrate 10 is needed for this purpose. This seed layer 12 has to be removed again at the end of the process, as FIG. 3d shows, through the use of a suitable anisotropic etching step, in order to avoid a short circuit between the various electrodes 350.

In particular, in the case of the third embodiment, a photolithographically structured photoresist 300 is used as the shape-imparting layer. The enlargement of the surface can be carried out in this case, for example, by using standing waves which results in a typically wavy side-wall profile in the photoresist. The profile can be transferred to the electrode structures by the filling process.

Although the invention has been described above using preferred exemplary embodiments, it is not restricted to these but can be modified in many ways.

Although the process of filling a structure with the electrode material has been described as a single-stage process, multi-stage processes may also be used. In particular, processes are considered in which, first of all, a thin surface layer is deposited into the mold or shape. The volume can then be filled with another electrode material. Multiple layers are likewise possible. ALCVD (atomic layer CVD) is a deposition technique which can likewise be used.

We claim:

1. A method of producing electrodes in one of a micromechanical device and a microelectronic device, the method which comprises:
producing a shape-imparting supporting structure on a substrate;
enlarging a surface of the shape-imparting supporting structure for providing an enlarged-surface, shape-imparting supporting structure; and
molding electrodes by using the enlarged-surface, shape-imparting supporting structure.

2. The method according to claim 1, which comprises carrying out a positive molding process for molding the electrodes.

3. The method according to claim 2, which comprises:
forming the enlarged-surface, shape-imparting supporting structure on a surface of the substrate;
filling the enlarged-surface, shape-imparting supporting structure with a filler material;
subsequently exposing a top of the enlarged-surface, shape-imparting supporting structure;
removing the enlarged-surface, shape-imparting supporting structure starting from the top of the enlarged-surface, shape-imparting supporting structure for forming cavities; and
filling the cavities with an electrode material for forming the electrodes.

4. The method according to claim 3, wherein the step of filling the cavities includes:
filling the cavities with the electrode material such that the electrode material forms a covering surface; and
subsequently, starting from the covering surface, removing the electrode material as far as a top of the filler material.

5. The method according to claim 3, wherein the step of filling the cavities includes growing the electrode material from a bottom as far as a top of the filler material.

6. The method according to claim 3, which comprises removing the filler material.

7. The method according to claim 4, which comprises removing the filler material.

8. The method according to claim 5, which comprises removing the filler material.

9. The method according to claim 1, which comprises carrying out a negative molding process for molding the electrodes.

10. The method according to claim 9, which comprises:
forming the enlarged-surface, shape-imparting supporting structure on a surface of the substrate; and
filling the enlarged-surface, shape-imparting supporting structure with the electrode material.

11. The method according to claim 10, wherein the filling step includes:
filling cavities with the electrode material such that a surface of the enlarged-surface, shape-imparting supporting structure is covered; and
subsequently removing the electrode material as far as a top of the enlarged-surface, shape-imparting supporting structure.

12. The method according to claim 10, wherein the filling step includes filling cavities with the electrode material by growing the electrode material from a bottom as far as a top of the enlarged-surface, shape-imparting supporting structure.

13. The method according to claim 10, which comprises removing the enlarged-surface, shape-imparting supporting structure.

14. The method according to claim 11, which comprises removing the enlarged-surface, shape-imparting supporting structure.

15. The method according to claim 12, which comprises removing the enlarged-surface, shape-imparting supporting structure.

16. The method according to claim 1, wherein the enlarging step uses a process selected from the group consisting of a hemispherical grain formation process for polysilicon, a nucleation island growth process, a process of forming standing waves in a photoresist, and a process of forming mesospores in silicon.

17. The method according to claim 16, wherein the nucleation island growth process includes forming polysilicon on an amorphous underlayer.

18. The method according to claim 17, which comprises using one of SiN and SiO₂ as the amorphous underlayer.

19. The method according to claim 3, wherein the filling step includes a process selected from the group consisting of a chemical vapor-phase deposition, an atomic layer chemical vapor-phase deposition, an electrochemical deposition, and a spin-on application.

20. The method according to claim 10, wherein the filling step includes a process selected from the group consisting of a chemical vapor-phase deposition, an atomic layer chemical vapor-phase deposition, an electrochemical deposition, and a spin-on application.

21. The method according to claim 1, which comprises depositing a thin layer of at least a first electrode material into the shape-imparting supporting structure and filling a remaining volume with a second electrode material.

22. The method according to claim 3, wherein the step of exposing the top of the enlarged-surface, shape-imparting supporting structure includes one of a chemical mechanical polishing step and an etching-back step.

23. The method according to claim 11, wherein the step of removing the electrode material as far as the top of the enlarged-surface, shape-imparting supporting structure includes one of a chemical mechanical polishing step and an etching-back step.

24. The method according to claim 1, which comprises using, as the electrode material, a material selected from the group consisting of Pt, Ir, IrO₂, Ru, RuO₂, SrₓRu_{y}O_{z}, W, WN, WSi, Ta, TaN, Ti, TiN, Mo, MoN, and Al, where x, y, z, are positive real numbers.
